(19) United States
(12) Patent Application Publication
(10) Pub. No.: US 2026/0299009 A1
(43) Pub. Date: Oct. 1, 2026

(54) ELECTRICAL SAFETY ANALYZER WITH MULTIMODAL GUIDANCE

(71) Applicant: Fluke Corporation, Everett, WA (US)

(72) Inventors: Anders Lindstrom, Göteborg (SE); Steven Parsons, Bothell, WA (US); Marcus Boyton, Göteborg (SE); Albin Anner, Göteborg (SE)

(21) Appl. No.: 19/093,766

(22) Filed: Mar. 28, 2025

(51) Int. Cl. G01R 31/28

(52) U.S. Cl. CPC G01R 31/2844; G01R 31/2839

(57) ABSTRACT

Provided is an electrical safety analyzer with multimodality guidance. The electrical safety analyzer identifies, for a test performed on a device under test, one or more terminals of a plurality of terminals on an electrical safety analyze. The electrical safety analyzer provides multi-modality guidance to couple the one or more terminals to one or more applied parts of the device under test.

### BACKGROUND

### Technical Field

This application is directed to an electrical safety analyzer (ESA) with multimodal connectivity guidance, and, in particular, an electrical safety analyzer that guides a user by activating and deactivating terminals light indicators and displaying terminal position information.

### Description of the Related Art

Electrical safety analyzers enable fast automated testing in healthcare settings. Electrical safety analyzers, which may be portable devices, perform electrical safety testing on medical equipment in the field and in healthcare facilities. Electrical safety analyzers are versatile and can perform wide-ranging evaluations from simple testing to comprehensive analyses.

Medical devices, such as defibrillators, electrocardiography (ECG) monitors and patient monitoring systems, are subjected to routine electrical safety testing. The testing ensures that the medical device function properly and may be safely connected to patients. Electrical safety analyzers are used by healthcare technology professionals to verify that medical devices meet relevant safety standards. Typically, an electrical safety analyzer includes terminals, which are connected to the applied parts (e.g., ECG leads or defibrillator pads) of a medical device. The electrical safety analyzer performs safety measurements on the medical device and applied parts thereof, including leakage current measurement and insulation resistance measurement, among others.

Evaluating a medical device using an electrical safety analyzer involves performing complex tests. Complex tests are typically associated with high incidences human error. A complex test may have different subparts (or subtests) and may involve connecting multiple applied parts (e.g., ECG leads or defibrillator pads) of a medical device to terminals of the electrical safety analyzer in different configurations. The complexity increases the likelihood of user misconnection errors. A misconnection leads to providing false measurements to the user due to the fact that accurate measurement is contingent on connecting the medical device (or the applied parts thereof) to designated terminals the analyzer. For example, if a user misconnects leads (whether by connecting the leads to the wrong terminals of the analyzer or incorrectly grouping the leads), it becomes more likely that the electrical safety analyzer will provide false measurement data. False measurements can be harmful and can result in approving medical devices that are unsafe for use on patients.

Conventional electrical safety analyzers lack real-time user guidance and typically rely on user manual information or terminal (or port) labeling to guide users in making connections between the medical device and an analyzer. However, labeling or static diagrams may be overlooked by users, particularly, in busy hospital or clinical environments, and do not provide lack dynamic or real-time indication that informs the user of which terminals should be used for a given test configuration.

Conventional electrical safety analyzers do not sufficiently mitigate user errors that occur when connecting a medical device under test, particularly, when multiple applied parts or patches (or extensions) thereof are connected to an analyzer. For example, a misconnection may occur when a user misconstrues a user manual or inattentively consults the user manual. An electrical safety analyzer may produce a measurement based on the erroneous connection without alerting the user that the setup is wrong. This increases the likelihood of a false “pass” and mistakenly deeming that a medical device is compliant with a safety standard when compliance has not been established.

Additionally, conventional electrical safety analyzers do not employ automatic error detection or correction. Conventional electrical safety analyzers do not automatically detect that an applied part has been misconnected. Thus, a user may not be informed that a misconnection has been made.

Accordingly, there is need for a robust, user-friendly and guidance-based electrical safety analyzer that reduces the likelihood of misconnections and false measurements.

### BRIEF SUMMARY

Provided is an electrical safety analyzer that gives multimodal guidance to a user. Multimodal guidance includes using multiple modes or ways of communicating to convey guidance or instructions, encompassing visual cues, graphical diagrams, spatial visualization interface, spatial arrangements, spatial patterns, lights, audio, text, and the like. The guidance enables the user to correctly connect a medical device under test (or applied parts thereof) to the electrical safety analyzer. The electrical safety analyzer includes terminals that the user connects to the applied parts of the medical device. The electrical safety analyzer dynamically indicates which terminals are to be connected for specific tests by activating light indicators positioned in a proximity of the terminals (for example, light indicators that are paired with the terminals). The electrical safety analyzer additionally displays a spatial visualization interface including a GUI element that represents the corresponding correct terminals using a matching diagram. The diagram matches a layout of the terminals on a hardware (e.g., front panel) of the electrical safety analyzer and light emitted by the light indicators. Multimodality guidance reduces the chance of users connecting the applied parts to the wrong terminals. For example, even if a user momentarily makes a misconnection, the illuminated light indicators serve as a direct alert to the user.

### BRIEF DESCRIPTION OF THE SEVERAL VIEWS OF THE DRAWINGS

FIG. 1 shows a block diagram of an electrical safety analyzer in accordance with an embodiment of the present disclosure.

FIG. 2 shows an example of a front panel of the electrical safety analyzer.

FIG. 3 shows a display, terminals and light indicators of the electrical safety analyzer.

FIG. 4 shows a flow diagram of a method for user configuration of the electrical safety analyzer.

FIGS. 5A and 5B show the display, the terminals and the light indicators of the electrical safety analyzer during user multimodal guidance for medical device testing.

FIGS. 6A and 6B show a flow diagram of a method for guiding the user through testing the medical device.

### DETAILED DESCRIPTION

Provided are techniques that reduce misconnection errors and false measurements when testing different applied parts of a medical device using an electrical safety analyzer.

In particular, an electrical safety analyzer having multimodal guidance is provided. The multimodal guidance visually directs the user to the appropriate terminals to which to connect applied parts (e.g., ECG leads or defibrillator pads) of a group of applied parts. Optionally, the multimodal guidance employs light indicator (e.g., LED) cues on hardware terminals and a spatial visualization interface that includes GUI indications to provide a dynamic and group-based instructions on connectivity to a user. The multimodal guidance of the analyzer reduces user misconnections and incorrect safety test results. Whereas labeling and textual instructions are static, multimodal guidance provides real-time illuminated connectivity information and clear and direct prompts. The multimodal guidance substantially mitigates the risk of human error, reduces false measurements and measurement error rates, enhances patient safety and improves regulatory compliance.

Provided is an electrical safety analyzer that gives multimodal guidance to a user. The guidance enables the user to correctly connect a medical device (or applied parts thereof) to the electrical safety analyzer. The electrical safety analyzer includes terminals that the user connects to the applied parts of the medical device. Optionally, the electrical safety analyzer dynamically indicates which terminals are to be connected for specific tests by activating light indicators positioned in a proximity of the terminals (for example, light indicators that are paired with the terminals). Optionally, the electrical safety analyzer additionally displays a spatial visualization interface including a GUI element that represents the corresponding correct terminals using a matching diagram. The diagram matches a layout of the terminals on a hardware (e.g., front panel) of the electrical safety analyzer and light emitted by the light indicators. Multimodality guidance reduces the chance of users connecting the applied parts to the wrong terminals. For example, even if a user momentarily makes a misconnection, the illuminated light indicators serve as a direct alert to the user.

Each terminal of the electrical safety analyzer is associated with a light indicator. Optionally, the electrical safety analyzer activates or deactivates the light indicators of the terminal based a test configuration. Optionally, the electrical safety analyzer may only illuminate the light indicators of terminals that are to be connected by the user. Optionally, the electrical safety analyzer may keep the light indicators illuminated during the time when the user is prompted to connect applied parts of a medical device to the terminals and during the time when results of a measurement are displayed. Accordingly, the likelihood of a misconnection is reduced. For example, if a terminal light indicator is not illuminated, the user is immediately alerted that the terminal is not active or used for an ongoing test.

Optionally, the electrical safety analyzer allows user interface integration. Optionally, the electrical safety analyzer enables a user to use an interface (e.g., touchscreen display) to associate (or correlate) a description of a group of applies parts (e.g., “ECG leads”) with a corresponding color, thereby providing an intuitive method for verifying that correct connections are made.

Optionally, the electrical safety analyzer provides real-time visual guidance. Optionally, when a test configuration is selected, the electrical safety analyzer illuminates the light indicators corresponding to active terminals for the test, thereby informing the user of the terminals to be connected to the applied parts of the medical device. Optionally, the electrical safety analyzer continues to illuminate the light indicators during the measurement and when the results are displayed to provide the user with a confirmation that the applied parts were connected to the proper terminals.

Optionally, the electrical safety analyzer may perform multi-part tests, whereby each part may require the user to connect different applied parts to different terminals. Optionally, as the electrical safety analyzer progresses from one test part to another test part or from one subtest to another subtest, the electrical safety analyzer dynamically guides the user to disconnect an applied part from one terminal and connect the applied part to another terminal.

Optionally, the terminals of the electrical safety analyzer may be connected to a frontend or controller of the analyzer using respective relays. Optionally, the electrical safety analyzer may selectively switch the relays on and off to activate and deactivate the paths from the terminals to the frontend or controller. Optionally, the electrical safety analyzer may activate a path of a terminal if the terminal is used in a present test. Optionally, the electrical safety analyzer may deactivate the path if the terminal is unused in a present test. Thus, human errors and the risk of false measurements are mitigated.

Optionally, the electrical safety analyzer may provide a connection error warning. For example, if a user connects an applied part to the wrong terminal, the electrical safety analyzer may detect the error and provide an audible or visual warning or alert. Additionally or alternatively, the electrical safety analyzer may refrain from performing a test if the electrical safety analyzer detects that a terminal has not been connected to an applied part, thereby reducing the likelihood of a false “pass”.

Optionally, the electrical safety analyzer may be configured to perform one or more tests on different groups of applied parts. The groups of applied parts may be of the same type or of different types. A type of an applied part may be an ECG lead or a defibrillator pad. Each group may be assigned a set of terminals on the analyzer. A user interface allows the user to designate the number of applied parts in each group, whereby, for example, the user may designate that a first group has ECG leads and a second group has two defibrillator pads. The electrical safety analyzer has an extendable configuration for various tests. Light indicator (e.g., LED) guidance is dynamically adapted to different test setups. For example, if a user reconfigures a test group to include more ECG leads or fewer defibrillator pads, the electrical safety analyzer automatically adjusts which terminals are illuminated. This flexibility allows the electrical safety analyzer to handle a wide range of medical equipment tests with minimal confusion or training overhead and has the extensibility or adaptability to cover future tests under future standards. The standards that govern medical device safety may be national or international electrical code, device safety or laboratory test standards.

The techniques described herein improve test validity and minimize the risk of inadvertently certifying a faulty medical device for use. That is due to the fact that correct connections between a medical device and an analyzer are a requisite for accurate measurements. The techniques described herein enhanced safety and compliance. Medical devices that pass safety tests under false assumptions can pose significant risks to patients. By guiding the user to establish correct connections, the multimodal guidance analyzer aids in ensuring that devices pass or fail testing accurately, thereby enhancing overall patient safety and supporting compliance with stringent regulatory requirements.

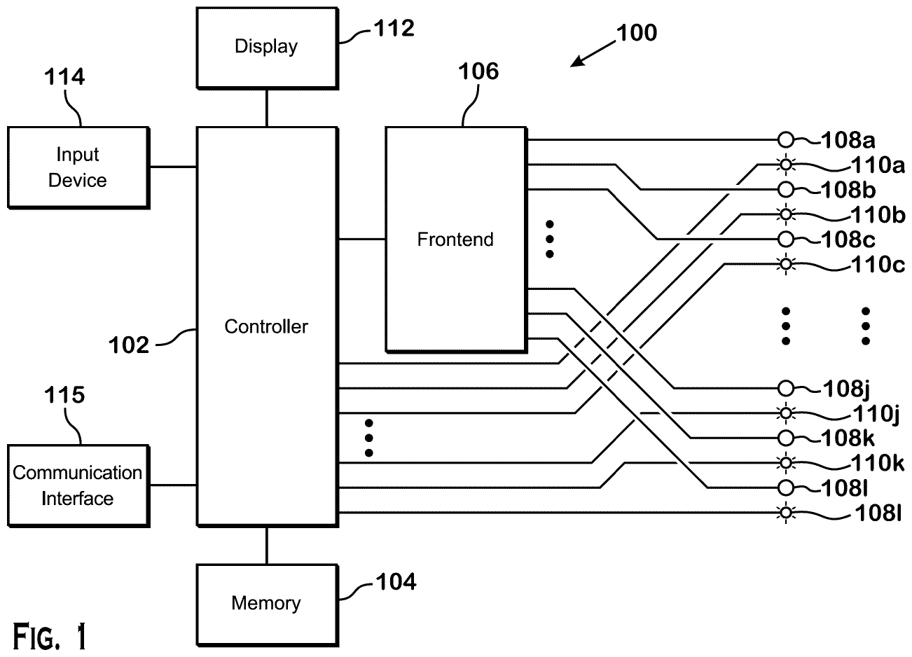

FIG. 1 shows a block diagram of an electrical safety analyzer 100 in accordance with an embodiment of the present disclosure. The electrical safety analyzer 100 includes a controller 102, a memory 104, a front-end 106, a plurality of terminals 108a-l, a plurality of light indicators 110a-l, a display 112, an input device 114 and a communication interface 115. The controller 102 is operatively coupled to the memory 104, the front-end 106, the plurality of light indicators 110a-l, the display 112, the input device 114 and the communication interface 115. The front-end 106 is coupled to the plurality of terminals 108a-l.

Although an electrical safety analyzer 100 is described here, the techniques provided herein may be used in any electrical testing or calibration device. The electrical safety analyzer 100 may be a portable analyzer that is used in a healthcare setting. The electrical safety analyzer 100 may perform electrical safety testing on medical equipment in the field and in medical facilities. Medical devices, such as defibrillators, electrocardiography (ECG) monitors and patient monitoring systems, are subject to routine electrical safety testing. The testing verifies that the medical devices operate correctly and safely. Electrical safety analyzers are used by technicians and healthcare technology professionals to verify that the medical devices meet relevant safety standards. The safety standards may specify series of test that are to be performed on the medical device to certify the device as safe for using on patients. Certification of the medical device is contingent on the device “passing” the series of tests. For example, terminals 108a-l of the electrical safety analyzer 100 are coupled to applied parts of the medical device to perform a test. The applied parts may be pads or leads of the medical device that are operable to contact a patient's body. The applied parts may be ECG leads or defibrillator pads, among others. The electrical safety analyzer 100 measures an electrical quantity of the applied parts (such as a leakage current and/or an insulation resistance, among others) to aid in determining whether the medical device (or applied parts thereof) may be safely used on patients.

The plurality of terminals 108a-l each include an electrical conductor that is operable to make electrical contact with an applied part (or a conductor thereof) of a medical device. For example, the applied part may be coupled to the terminal 108a-l or a test probe, test lead or cable of the electrical safety analyzer 100 may be coupled to the applied part of the medical device. After coupling the electrical safety analyzer 100 to the applied parts of the medical device, the electrical safety analyzer 100 may make electrical measurements in order to test the medical device.

The controller 102 may be any type of device that is configured to execute instructions (computer-executable instructions) that cause the electrical safety analyzer 100 to operate as described herein. For example, the controller 102 may be a processor or a microcontroller and may include a central processing unit (CPU) including an arithmetic and logic unit (ALU), a graphics processing unit (GPU), or any other type of processing unit.

The controller 102 receives user input for configuring operation of the electrical safety analyzer 100 using the input device 114 and/or the display 112, which may be a touchscreen display, as described herein. The controller 102 commands the display 112 to display information to the user and commands the front-end 106 to process an electrical quantity detected over one or more of the plurality of terminals 108a-l. The controller 102 also commands the plurality of light indicators 110a-l to emit light having a specific color.

The memory 104 may be any type of non-transitory computer-readable storage medium. The memory 104 may be read-only memory (ROM) or random access memory (RAM), among others. Further, the memory 104 may be static or dynamic. The memory 104 stores the computer-executable instructions that may be retrieved or accessed by the controller 102 for execution. The computer-executable instructions, when executed by the controller 102, cause the controller 102 (and consequently the electrical safety analyzer 100) to operate as described herein.

The front-end 106 includes a circuitry configured to detect an electrical quantity of one or more terminals of the plurality of terminals 108a-l. The circuitry may include relays, amplifiers, filters, application-specific integrated circuits (ASICs), and analog components (such as resistors, capacitors, inductors, and transistors), among others. The front-end 106 may include a plurality of channels, whereby each channel may be coupled to one terminal 108a-l. For example, a first channel may be coupled to a first terminal 108a of the plurality of terminals 108a-l, and a second channel may be coupled to a second terminal 108b of the plurality of terminals 108a-l.

The display 112 may be any type of visual output device configured to output data to a user. In addition, the display 112 may be a touchscreen display that operates as an input device. The display 112 is configured to receive user input for configuring operation of the electrical safety analyzer 100. The display 112 may receive a user configuration of a multi-part test to be run by the electrical safety analyzer 100. Each constituent part of the multi-part test may pertain to different applied parts of the medical device or to the measurement of a different electrical quantity of the applied parts. For example, the configuration may include, for each part of the test, a number of applied parts (e.g., leads or pads of the medical device) that are to be coupled to the electrical safety analyzer 100. The display 112 may also receive a user selection of a preconfigured multi-part test. After the electrical safety analyzer 100 identifies the terminals 108a-l that are to be coupled to applied parts of the medical device, the display 112 may display, to the user, information that conveys the terminals 108a-l that are to be coupled to applied parts of the medical device. The display may display a position of the terminals 108a-l that are to be coupled to applied parts of the medical device. For example, the display 112 may display a layout of the terminals and may indicate the terminals 108a-l that are to be coupled to applied parts of the medical device within the layout. The display 112 may be a color display, and the color associated with the displayed position of the terminals 108a-l may be synchronized (e.g., matched to or the same as) a color of light indicators 110a-l positioned in association with the terminals 108a-l.

A light indicator of the plurality of light indicators 110a-l may be any light source or device configured to emit light. For example, the light indicator may be a light-emitting diode (LED) or organic light-emitting diode (OLED), among others. The light indicator may be configured to emit multiple colors. The controller 102 may command the light indicator to emit a specific color and switch between colors. Each light indicator is associated with a respective terminal of the plurality of terminals 108a-l. A light indicator may be positioned proximate to the respective terminal such that a user associates the light indicator with the respective terminal. For example, the light indicator may be adjacent to the terminal or may surround the terminal.

The input device 114 may be any type of device configured to receive user input. The input device 114 may be a keypad, buttons, or a scroll wheel, among others. The input device 114 may be a device that is internal to the analyzer 100 or an external device. For example, the input device may be a universal serial bus (USB) port and having a USB keyboard or the like connected thereto. A user may use the input device 114 to configure the electrical safety analyzer 100 and functionality thereof. The input device 114 may be a touch feature of the display 112 that allows inputting user commands.

The communication interface 115 may be a port, modem, transmitter, receiver or transceiver, among others. The communication interface 115 may be wired or wireless and may be configured to communicate with an external device. The communication interface 115 may communicate with the external device and may receive data from the external device. The data may include a pre-configured multi-part test for use by the electrical safety analyzer 100. For example, a multi-part test may be imported to the electrical safety analyzer 100 over the interface from an external computer, which alleviates the need for the user to specify the test using the input device.

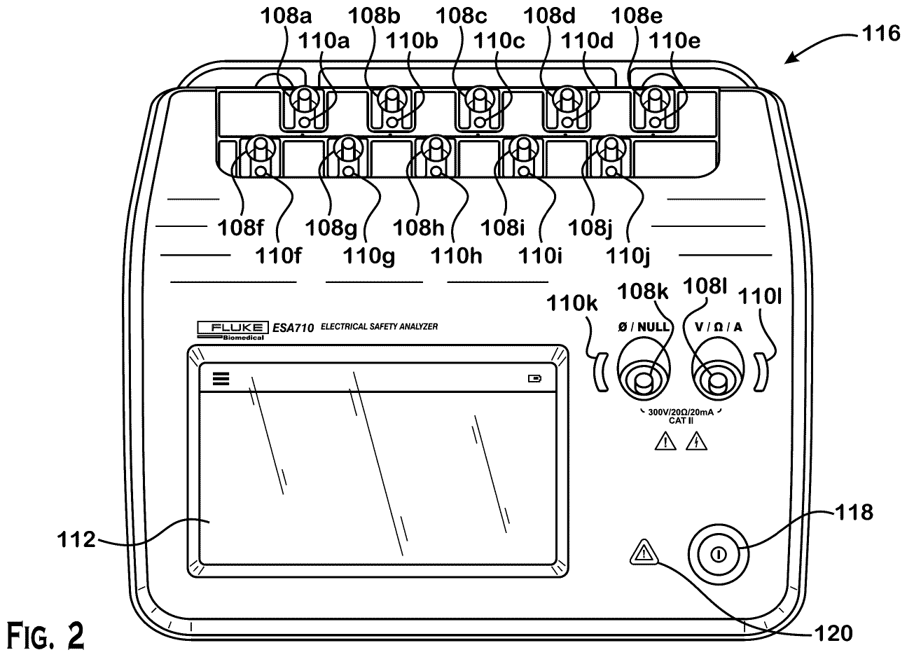

FIG. 2 shows an example of a front panel 116 of the electrical safety analyzer 100. The front panel 116 includes the plurality of terminals 108a-l, the plurality of light indicators 110a-l, the display 112, a power button 118 and a warning indicator 120. The plurality of terminals 108a-l are respectively associated with the plurality of light indicators 110a-l. As shown in FIG. 2, a first set of light indicators 110a-e are adjacent to each other and positioned below a respective first set of terminals 108a-e and a second set of light indicators 110f-j are adjacent to each other and are positioned below a respective second set of terminals 108f-j. The light indicators 110k, 110l are positioned next to their respective terminals 108k, 108l.

In addition or as an alternative to the one-to-one correspondence between the plurality of terminals 108a-l and the plurality of light indicators 110a-l, there may be a one-to-many correspondence between terminals and light indicators. A group of terminals (e.g., two, three or four) may be associated with one light indicator. The plurality of terminals 108a-l may include some terminals that each have one-to-one correspondence to respective light indicators and one or more other groups of terminals. Each group of terminals may be associated with one respective light indicator.

The user may actuate the power button 118 (e.g., by pressing the power button) to power on the electrical safety analyzer 100. The electrical safety analyzer 100 may illuminate the warning indicator 120 indicator to alert the user. The warning indicator 120 may indicate a hazardous condition (e.g., high voltage). The electrical safety analyzer 100 may illuminate the warning indicator 120 to indicate to the user that an applied part was connected to the wrong terminal, for example, in the event that the electrical safety analyzer 100 detects that a connection has been made to an unused or inactive terminal for an ongoing test. The electrical safety analyzer 100 may illuminate the warning indicator 120 to indicate to the user that a connection has not been made to an active terminal of an ongoing test. Additionally or alternatively, a light indicator corresponding to a terminal may blink to indicate a potential incoming hazard or illuminate solid light (such as red light) to indicate an active hazard.

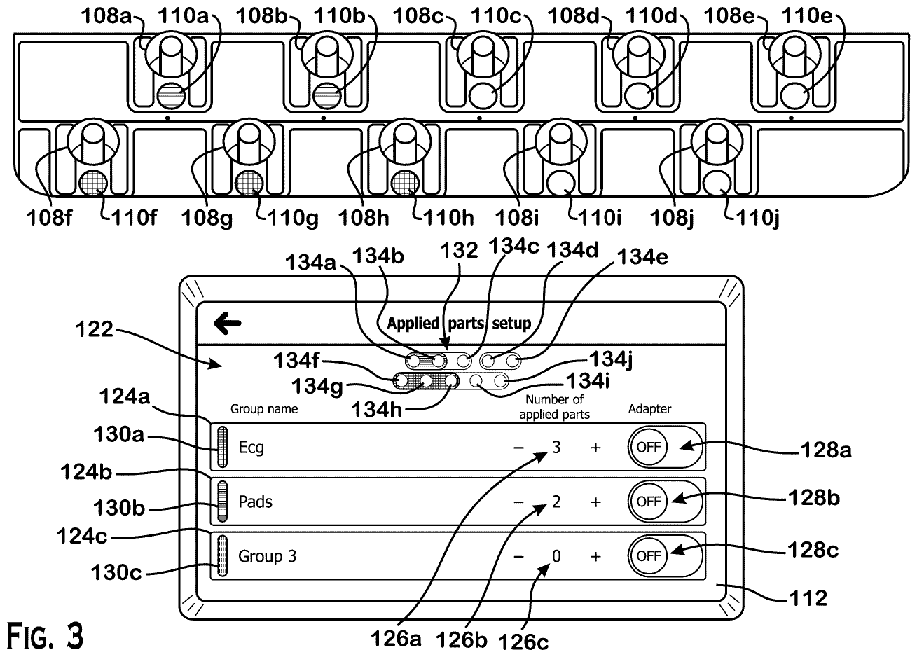

FIG. 3 shows the display 112, the first and second sets of terminals 108a-e, 108f-j and the first and second sets of light indicators 110a-e, 110f-j of the electrical safety analyzer 100 in accordance with an embodiment. To facilitate description, remaining elements of the electrical safety analyzer 100 are not shown in FIG. 3.

The display 112 presents a configuration menu 122 to the user. The configuration menu 122, which is also referred to as an applied parts setup, permits a user to specify a type or group of applied parts that are to be coupled to the terminals 108a-j and a number of applied parts included in the group or type. For example, the group of applied parts may be three ECG leads or two defibrillator pads. The configuration menu 122 presents a plurality of editable graphical user interface (GUI) elements 124a-c through which the user may specify a plurality of groups of applied groups, respectively. For each group, the configuration menu 122 displays a respective editable GUI element 126a-c through which the user may specify the number of applied parts pertaining to the group specified by the element 124a-c. An editable GUI element 126a-c may include an increment GUI element and a decrement GUI element. The increment GUI element may permit the user to increase the number of applied parts and a decrement GUI element may permit the user to decrease the number of applied parts. Additionally or alternatively, the editable GUI element 126a-c may allow the user to key in the number of applied parts.

For each applied parts group, the configuration menu 122 presents a plurality of GUI elements 128a-c that permit the user to specify whether the applied parts are to be coupled to the terminals 108a-j with or without an adapter. If the GUI element 128a-c reads “OFF”, then that suggests that the user is to couple the applied parts of the relevant group without an adapter. If the GUI element 128a-c reads “ON”, then that suggests that an adapter is used. For example, the plurality of GUI elements 128a-c may permit the user to toggle between “OFF” and “ON.”

Furthermore, for each applied parts group, the configuration menu 122 presents a plurality of GUI elements 130a-c indicating a color associated with the applied parts group. The color may be synchronized to a color emitted by the light indicators 110a-j that are positioned in association with the terminals 108a-j to which the applied parts of the group are coupled. For example, GUI elements 124a, 126a specify that three ECG leads are to be coupled to the electrical safety analyzer 100. GUI element 130a shows a yellow color (denoted by cross hatching in FIG. 3) and indicates that the light indicators that are positioned in association with the terminals to which the three ECG leads are to be coupled emit yellow light. Further, GUI elements 124b, 126b specify that two defibrillator pads are to be coupled to the electrical safety analyzer 100, and GUI element 130b shows a blue color (denoted by cross hatching in FIG. 3) and indicates that the light indicators that are positioned in association with the terminals to which the two defibrillator are to be coupled emit blue light.

The GUI elements 130a-c indicating the color associated with the applied parts group may be changeable by the user. For example, the user may change the yellow color associated with the three ECG leads and the blue color associated with the two defibrillator pads to different colors. Alternatively, the colors of the GUI elements 130a-c may be fixed in relation to the order on which they are presented on the display 112 and unchangeable. Accordingly, a first applied parts group on the list (as specified by GUI element 124a) remains associated with the color yellow, a second applied parts group on the list (as specified by GUI element 124b) remains associated with the color blue and a third applied parts group on the list (as specified by GUI element 124c) remains associated with the color purple (denoted by dashed vertical hatching in FIG. 3). The user may associate the applied parts with any color.

The display 112 also shows a spatial visualization interface 132 that has a positional information GUI element including diagrammatical representations 134a-j of the terminals 108a-j, respectively. The diagrammatical representations 134a-j are shown in positions corresponding to the respective positions of the terminals 108a-j on the front panel 116. That is, the diagrammatical representations 134a-j may be placed in positions in a layout that correspond (e.g., match) the positions of the terminals 108a-j on the analyzer 100. The layout may readily convey to the user that the diagrammatical representations 134a-j relate to the terminals 108a-j. Each diagrammatical representation 134a-j is linked to a respective terminal 108a-j having a position (in relation to other terminals 108a-j) on the analyzer 100 that conforms to the position of the diagrammatical representation 134a-j (in relation to other diagrammatical representation 134a-j in the spatial visualization interface 132).

For example, the spatial visualization interface 132 shows two rows, each having five circles. A circle in a row corresponds to a terminal 108a-j of the panel 116. The circles of the top row are offset from the circles of the bottom rows similar to the offset between the first set of terminals 108a-e and the second set of terminals 108f-j on the panel 116. It is noted that the shape of a diagrammatic representation may be the same or different than a shape of the terminal

The positional information GUI element of the spatial visualization interface 132 may also associate the diagrammatic representations 134a-j with a color. The color may be a color of the GUI element 130a-c to which the terminal belongs. For example, the diagrammatic representations 134f, 134g, 134h are associated with the color blue to suggest to the user that the three ECG leads of GUI element 124a (that are also associated with the blue color) will be coupled to terminals 108f, 108g, 108h during testing.

The spatial visualization interface 132 may react to user input. The analyzer 100 may increase (or decrease) the number of diagrammatic representations 134f, 134g, 134h are associated with the color blue as the user increases of decreases the number of applied parts for the group specified by GUI element 126a.

The color may be synchronized with a color that is or will be emitted by the light indicators 110a-j (e.g., during test configuration or during testing). A diagrammatical illustration 134a-j of a terminal 108a-j in the spatial visualization interface 132 may have the same color as the color emitted by the light indicator 110a-j associated with the terminal 108a-j during testing. The diagrammatical illustration 134a-j in the spatial visualization interface 132 may itself have the color or the diagrammatical illustration 134a-j may be surrounded by the color.

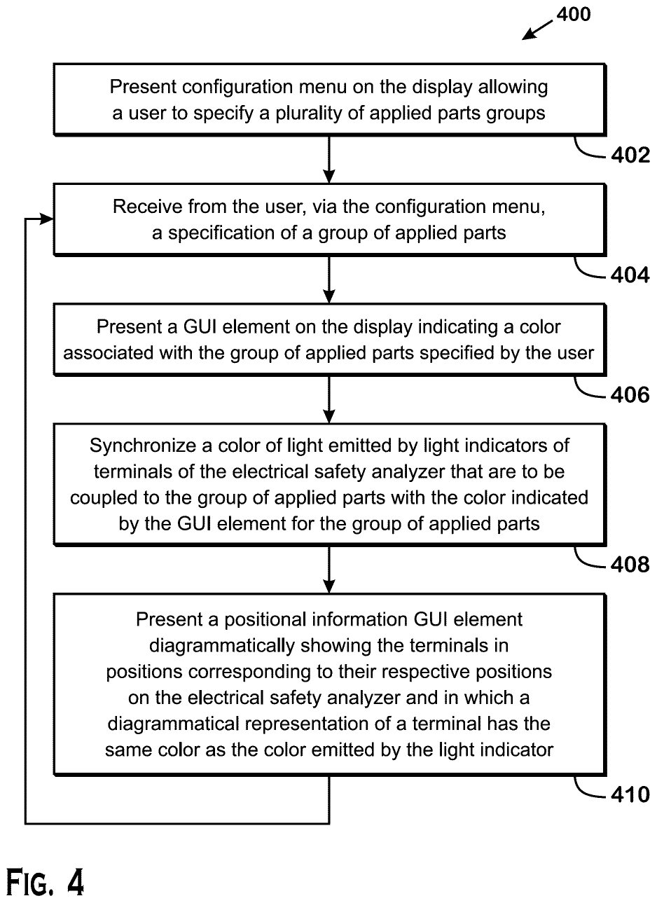

FIG. 4 shows a flow diagram of a method 400 for user configuration of the electrical safety analyzer 100. In the method 400, the electrical safety analyzer 100 presents, at 402, the configuration menu 122 to a user on the display 112. As described herein, the configuration menu 122 includes GUI elements 124a-c for the user to specify a plurality of groups of applied parts, GUI elements 126a-c for the user to specify a number of applied parts for each group and GUI elements 128a-c for the user to specify whether the applied parts are coupled with or without an adapter.

The electrical safety analyzer 100 receives, at 404, from the user, via the configuration menu, a specification of an applied parts group. For example, the user may specify that the applied parts group is pads or leads. The electrical safety analyzer 100 presents, at 406, GUI elements on the display indicating a color associated with each group specified by the user. The color may be changeable by a user as described herein. The electrical safety analyzer 100 synchronizes, at 408, a color of light emitted by light indicators of terminals of the electrical safety analyzer that are to be coupled to the group of applied parts with the color indicated by the GUI element for the group.

The electrical safety analyzer 100 presents, at 410, a positional information GUI element on the display 112 diagrammatically showing the terminal 108a-j in positions corresponding to their respective positions on the electrical safety analyzer and in which a diagrammatical representation of a terminal 108a-j has the same color as the color emitted by a light indicator 110a-j of the terminal 108a-j. As described herein, the positional information GUI element, which may be part of the spatial visualization interface 132, reacts to user input and increases or decreases the number of diagrammatical representations that are associated with a particular color based on the number of applied parts specified by the user. The positional information GUI element informs the user of the groupings of terminals that will be utilized during testing.

The method 400 then reverts to 404 for remaining groups of applied parts that are specified by the user. For example, after steps 404, 406, 408 are performed for one applied parts group, the method 400 proceeds to reverts to 404 at which the electrical safety analyzer 100 receives from the user, via the configuration menu, a specification of another applied parts group and presents, at 406, a GUI element on the display indicating a color associated the other group, synchronizes, at 408, a color of light emitted by light indicators of terminals and presents, at 410, a positional information GUI element for the terminals.

The user may perform testing on the medical device based on the terminal usage configurations provided by the menu. The configuration of calls for testing three ECG leads using terminals 108f, 108g, 108h and testing two defibrillator pads using terminals 108a, 108b. After the test is configured, the analyzer 100 guides the user through connecting the leads and pads to the analyzer 100.

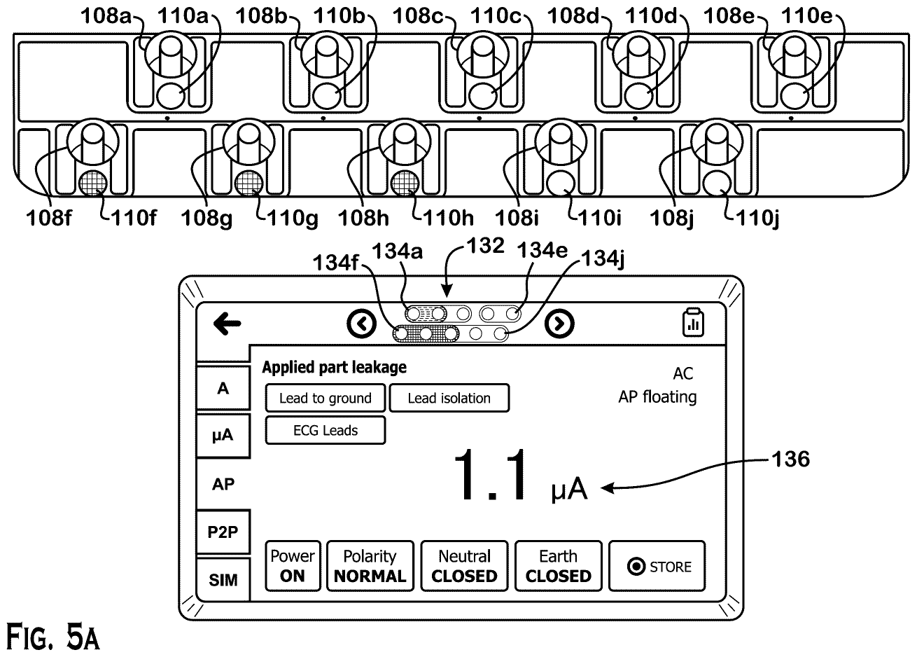

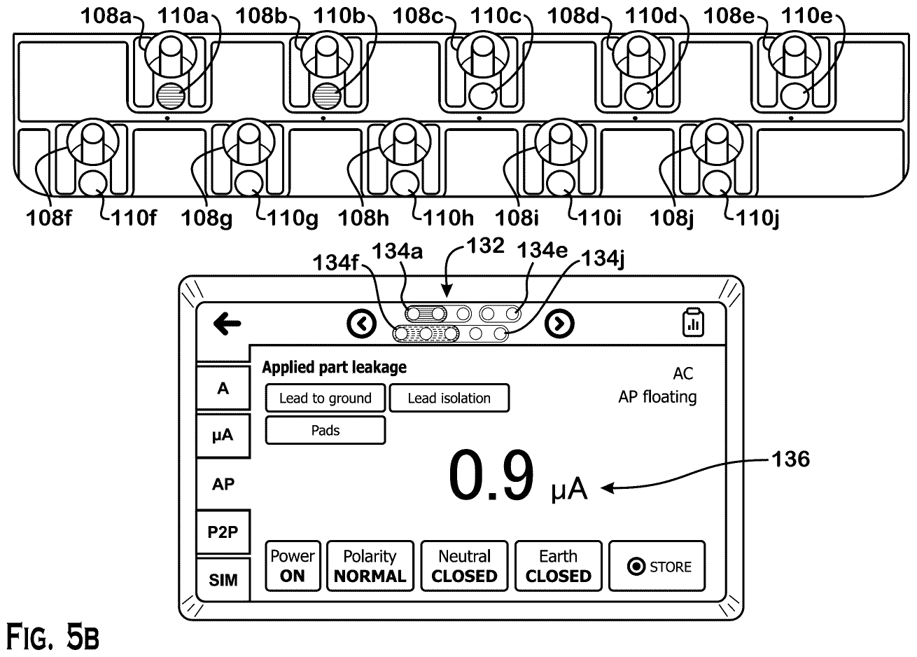

FIGS. 5A and 5B show the display 112, the terminals 108a-j and the light indicators 110a-j of the electrical safety analyzer 100 during user multimodal guidance for medical device testing. To facilitate description, remaining elements of the electrical safety analyzer 100 are not shown in FIGS. 5A and 5B.

The electrical safety analyzer 100 guides the user for testing each group of applied parts that are configured (e.g., using the configuration menu). FIG. 5A provides multimodal guidance for testing the three ECG leads specified by GUI element 124a and FIG. 5B provides multimodal guidance for testing the two defibrillator pads specified by GUI element 124b.

As described with reference to FIG. 3, the user configures ECG leads as a group of applied parts. The configuration menu 122 associates the ECG leads with the color yellow and specifies that three ECG leads are tested. After a test is launched, the electrical safety analyzer 100 provides multimodal guidance for the user for connecting the ECG leads to the electrical safety analyzer 100.

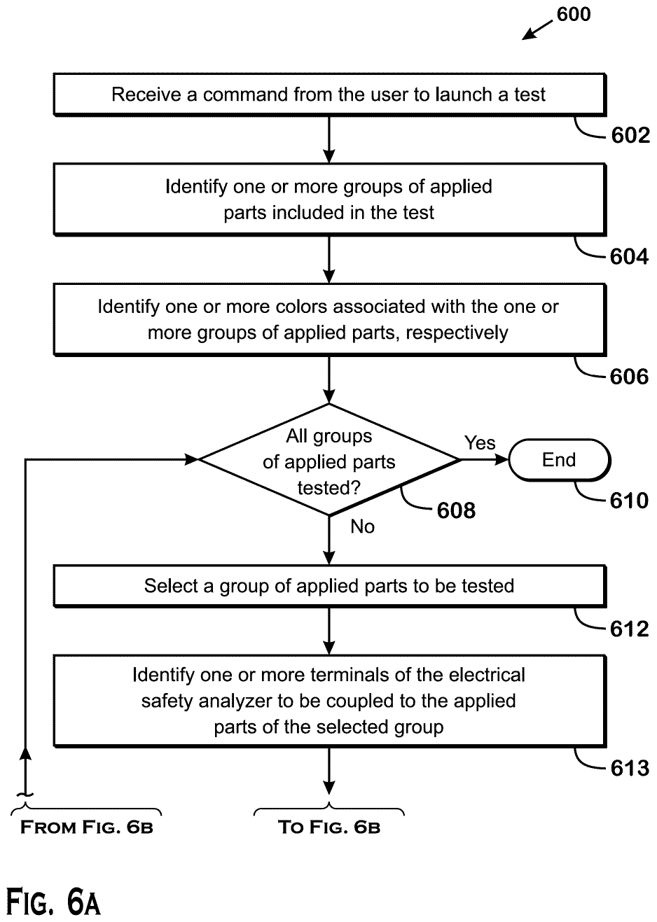

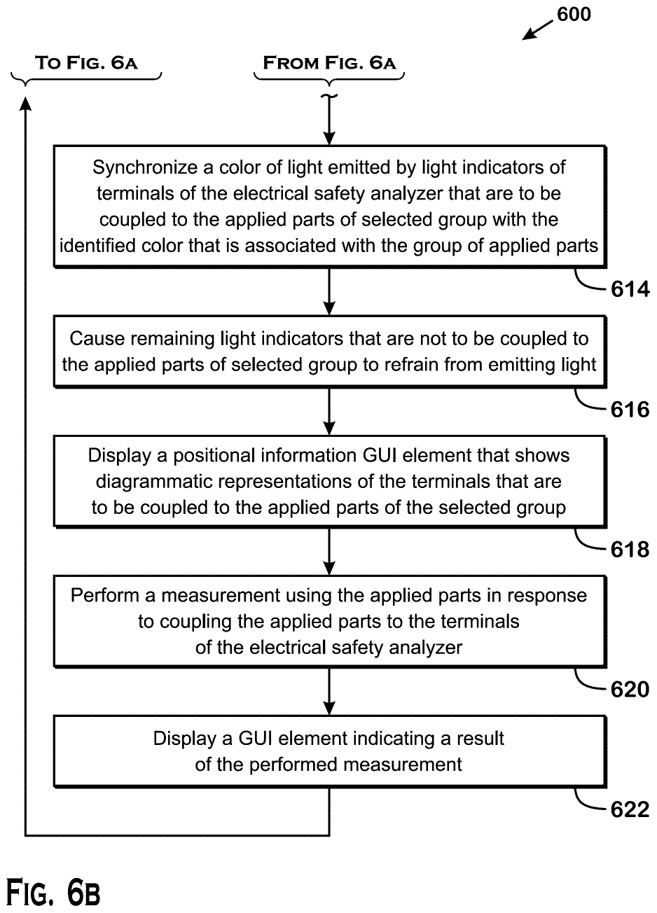

FIGS. 6A and 6B show a flow diagram of a method 600 for guiding the user through testing the medical device. In the method 600, the electrical safety analyzer 100 receives, at 602, a command from the user to launch a test. As described herein, the test may be a multi-part test and may include testing various groups of applied parts. The groups may be of the same type or of different types. The types of applied parts may be provided by the user through the configuration menu. Alternatively, the groups of applied parts to be tested may be imported to the electrical safety analyzer 100 from an external computer.

The electrical safety analyzer 100 identifies, at 604, one or more groups of applied parts included in the test. For example, the configuration menu shown in FIG. 3 specifies that the test includes ECG leads and defibrillator pads as two groups of applied parts.

The electrical safety analyzer 100 identifies, at 606, one or more colors associated with the one or more groups of applied parts, respectively. As described herein, the electrical safety analyzer 100 may identify the one or more groups of applied parts included in the test and the one or more colors associated with the one or more groups of applied parts, respectively, from the information received via the configuration menu. For example, the electrical safety analyzer 100 may store the information provided by the user through the configuration menu in the memory 104. The configuration menu of FIG. 3 specifies that the ECG leads are associated with a blue color (denoted by horizontal hatching in FIG. 3) and the defibrillator pads are associated with a yellow color (denoted by cross hatching in FIG. 3).

The identified color for each group is used for determining the color of light illuminated terminal light indicators. The identified color may also be used in the spatial visualization interface to provide an additional layer of guidance to the user. The identified color may be the same color provided by the configuration menu 122 for the group or a different color. Further, the electrical safety analyzer 100 may identify the same color for different groups or different colors for different groups.

The electrical safety analyzer 100 may test different groups individually and one at a time. Accordingly, illuminating the light indicators 110a-j using the same color (for multiple groups) or using colors that are inconsistent with those presented in the configuration menu 122 is unlikely to lead to connection mistakes by the user.

The electrical safety analyzer 100 determines, at 608, whether all groups of applied parts (e.g., provided via the configuration menu) have been tested. If a positive determination is made at 608, the method 600 ends at 610. Conversely, if a negative determination is made at 608, the electrical safety analyzer 100 selects, at 612, a group of applied parts to be tested. The electrical safety analyzer 100 may select the group of applied parts in order as listed on the configuration menu 122, whereby the ECG leads are selected first and the defibrillator pads are selected second. The electrical safety analyzer 100 identifies, at 613, one or more terminals of the electrical safety analyzer 100 to be coupled to the applied parts of the selected group (or that are applicable to a test). After the terminals are identified, the electrical safety analyzer 100 provides multimodal guidance to couple the terminals to the applied parts. It is noted that one terminal may be identified and the group may include one applied part to be coupled to the terminal.

The electrical safety analyzer 100 synchronizes, at 614, a color of light emitted by light indicators 110a-j of terminals 108a-j of the electrical safety analyzer that are to be coupled to the applied parts of selected group with the identified color that is associated with the selected group of applied parts. In the event that the color is identified from the user configuration, the electrical safety analyzer 100 causes three light indicators 110f, 110g, 110h of three terminals 108f, 108g, 108h to emit yellow light (denoted by cross hatching), as shown in FIG. 5A. In the event that the color is identified is white or another color, the electrical safety analyzer 100 causes the three light indicators 110f, 110g, 110h of the three terminals 108f, 108g, 108h to emit that color.

The electrical safety analyzer 100 causes, at 616, remaining light indicators that are not to be coupled to the applied parts of selected group to refrain from emitting light. The remaining light indicators are associated with terminals that are not to be connected by the user to the applied parts of the selected group. For example, in FIG. 5A, the three light indicators 110f, 110g, 110h emit light and the remaining light indicators 110a-e, 110i, 110j refrain from emitting light in order to better guide the user and aid in focusing user attention on the terminals 108f, 108g, 108h whose light indicators 110f, 110g, 110h emit light.

In addition the electrical safety analyzer 100 may deactivate the remaining terminals when they are not in active use. For example, each terminal 108a-j may be connected to the frontend 106 using a relay. Or the relay may be part of the frontend 106. The relay may be controlled by the controller 102. The controller 102 may selectively open the relay to electrically isolate a terminal 108a-j from the frontend 106 when the terminal is not used for a test and close the relay to connect the terminal 108a-j to the frontend 106 when the terminal is being used for a test. For example, in the configuration of FIG. 5A, the relays of terminals 108f, 108g, 108h may be closed and the relays of the remaining terminals 108a-e, 108i, 108j may be open.

The electrical safety analyzer 100 displays, at 618, a positional information GUI element on the display. The displayed positional information GUI element, which may be part of the spatial visualization interface 132, diagrammatically shows the terminals 108a-j that are to be coupled to the applied parts of the selected group. As explained herein, the positional information GUI element may diagrammatically show the terminals 108a-j of the analyzer 100 in positions corresponding to their respective positions on the front panel 116 of the analyzer 100.

To show the terminals to be coupled to the applied parts of the selected group, the displayed positional information GUI element may distinguish the diagrammatic representations 134a-j of the terminals 108a-j that are to be coupled to the applied parts of the selected group from other terminals. Distinguishing the diagrammatic representations 134a-j may include coloring the diagrammatic representations 134a-j themselves or their surroundings. Distinguishing the diagrammatic representations 134a-j may include highlighting or encircling the diagrammatic representations. Distinguishing the diagrammatic representations 134a-j may include isolating the diagrammatic representations from other diagrammatic representations. For example, a diagrammatical representation 134a-j in the positional information GUI element may have the same color as the color emitted by the light indicator 110a-j of the terminal 108a-j. Or, the diagrammatical representation 134a-j in the positional information GUI element may be adjacent to or surrounded by the color emitted by the light indicator 110a-j of the terminal 108a-j. In addition to illuminating the light indicators, the positional information GUI element of the spatial visualization interface 132 functions as an additional form of guidance for the user, providing a reference as to which terminals 108a-j the user should connect to the applied parts of the selected group.

As shown in FIG. 5A, the diagrammatic representations 134f, 134g, 134h of the terminals 108f, 108g, 108h that are to be coupled to the applied parts of the selected group are surrounded by a yellow color (denoted by cross hatching in FIG. 5A). The color may be the same or different than the color emitted by the light indicators 110f, 110g, 110h of the terminals 108f, 108g, 108h. On the other hand, terminals 108a, 108b are to be coupled to the defibrillator pads. The defibrillator pads are a group of applied parts included in the configured multi-part test, but not presently selected in the method 600 as part of an ongoing test. The diagrammatic representations 134a, 134b of the terminals 108a, 108b are associated with a grey color (denoted by horizontal dashed hatching in FIG. 5A) to denote that the terminals 108a, 108b are presently inactive, but will be active for another group of applied parts. The terminals 108c-e, 108i, 108j are unused in the multi-part test. The diagrammatic representations 134c-e, 134i, 134j of the unused terminals 108c-e, 108i, 108j are associated a different color to denote that the terminals 108c-e, 108i, 108j are unused.

It is noted that the positional information GUI element of the spatial visualization interface 132 shown in FIG. 5A is a non-limiting example. Other techniques for emphasizing or highlighting the diagrammatic representations 134f, 134g, 134h of the terminals 108f, 108g, 108h to be connected to the applied parts of the selected group include enclosing the representations 134f, 134g, 134h within a border or otherwise contrasting the diagrammatic representations 134f, 134g, 134h of the terminals 108f, 108g, 108h vis-à-vis the diagrammatic representations 134a-e, 134i, 134j of remaining terminals 108a-e, 108i, 108j.

With the aid of the illumination of light indicators 110f, 110g, 110h and of the display of the positional information GUI element of the spatial visualization interface 132, the user may readily identify the terminals 108f, 108g, 108h, which the analyzer 100 identifies are to connected to the applied parts (e.g., three ECG leads). If the electrical safety analyzer 100 detects that the user erroneously connected an applied part to a different terminal, then the electrical safety analyzer 100 may output an alert or warning to the user.

To better guide the user, the analyzer 100 may continue illuminating the light indicators 110f, 110g, 110h and displaying the positional information GUI element of the spatial visualization interface 132 while awaiting the user to connect the applied parts to the terminals 108f, 108g, 108h. The analyzer 100 may also continue illuminating the light indicators 110f, 110g, 110h and displaying the positional information GUI element of the spatial visualization interface 132 for a period of time after the user connects the applied parts and while displaying a measurement result for the applied parts. The additional time allows the user to confirm that a correct connection (or a connection in accordance with illuminated indicators and the GUI element) has been made.

Referring back to FIGS. 6A and 6B, the electrical safety analyzer 100 performs, at 620, a measurement using the applied parts in response to coupling the applied parts to the terminals of the electrical safety analyzer. Continuing with the example of FIG. 5A, the electrical safety analyzer 100 performs a measurement using the terminals 108f, 108g, 108h. For example, the electrical safety analyzer 100 may await until the user connects the applied parts to the terminals 108f, 108g, 108h and perform the measurement when the electrical safety analyzer 100 detects that the terminals 108f, 108g, 108h are connected to the applied parts. Detecting the connection may be made based on determining an impedance value that is couple to the terminals 108f, 108g, 108h.

The electrical safety analyzer 100 display, at 622, a GUI element indicating a result of the performed measurement. As shown in FIG. 5A, the electrical safety analyzer 100 display a GUI element 134 indicating that the leakage current of the ECG leads is 1.1 microamperes (μA). The method 600 reverts to 608, and the electrical safety analyzer 100 determines, at 608, whether all groups of applied parts have been tested. If a positive determination is made at 608, the method 600 ends at 610. Conversely, if a negative determination is made at 608, the electrical safety analyzer 100 selects, at 612, another group of applied parts to be tested and identifies terminals that are to be coupled to the group.

The electrical safety analyzer 100 may perform multiple tests on each group, such as leakage current and insulation resistance. The electrical safety analyzer 100 may continue performing the method 600 until the multiple tests are performed on each group. The user may command the electrical safety analyzer 100 to advance to a subsequent test and switch between tests.

Similar to FIG. 5A, FIG. 5B shows light indicator and spatial visualization interface multimodal guidance for testing two defibrillator pads that are paired in a group. To prompt the user to connect the pads to terminals 108a, 108b, the electrical safety analyzer 100 causes the light indicators 110a, 110b to illuminate. As described herein, the light indicators 110a, 110b may illuminate any color. For example, the light indicators 110a, 110b may illuminate blue light with which the group of defibrillator pads are linked in the configuration menu. The electrical safety analyzer 100 causes remaining light indicators 110c-j to refrain from emitting light as the remaining light indicators 110c-j are associated with terminals 108c-j that are not to be connected to the defibrillator pads.

The electrical safety analyzer 100 also displays the positional information GUI element of the spatial visualization interface 132 on the display 112. The positional information GUI element 132 shows diagrammatical representations 134a-j of the terminals 108a-j as laid out (or arranged) on the electrical safety analyzer 100 or a front panel 116 thereof. The diagrammatical representations 134a-j may have the same geometry in the GUI element as the terminals 108a-j on the electrical safety analyzer 100 or the front panel 116. As described herein, the diagrammatical representation 134a, 134b of the terminals 108a, 108b to be coupled to the pads may be distinguished (e.g., emphasized or highlighted) as compared to the diagrammatical representation 134c-j of the remaining terminals 108c-j. In FIG. 5B, the diagrammatical representation 134a, 134b are associated with the color blue (denoted by horizontal hatching) and the diagrammatical representations 134a, 134b are adjacent to and surrounded by the blue color.

The diagrammatic representations 134f, 134g, 134h of the terminals 108f, 108g, 108h are associated with a grey color (denoted by horizontal dashed hatching in FIG. 5B) to denote that the terminals 108f, 108g, 108h are presently inactive, but were or will be active for another group of applied parts. The terminals 108c-e, 108i, 108j are unused in the configured multi-part test. The diagrammatic representations 134c-e, 134i, 134j of the unused terminals 108c-e, 108i, 108j are associated a different color to denote that the terminals 108c-e, 108i, 108j are unused.

After the user connects the defibrillator pads to the terminals 108a, 108b, the electrical safety analyzer 100 performs a measurement on the pads. The electrical safety analyzer 100 displays the GUI element 136 indicating a result of the measurement. As shown in FIG. 5B, the electrical safety analyzer 100 measures the leakage current of the pads and displays the GUI element 136 indicating that the leakage current is 0.9 μA.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electrical safety analyzer, comprising:
a display;
a plurality of terminals having respective positions on the electrical safety analyzer, a terminal of the plurality of terminals being configured to make electrical contact with an applied part of a device under test;
a plurality of light indicators positioned in association with the plurality of terminals, respectively, and configurable to emit light; and
a controller configured to:
identify one or more terminals of the plurality of terminals applicable to a test; and
provide multimodal guidance to couple the one or more terminals of the plurality of terminals to one or more applied parts of the device under test.

2. The electrical safety analyzer as claimed in claim 1, wherein the controller is configured to provide the multimodal guidance by:
causing one or more light indicators positioned in association with the one or more terminals to illuminate.

3. The electrical safety analyzer as claimed in claim 1, wherein the controller is configured to provide the multimodal guidance by:
causing the display to display a spatial visualization interface with a positional information graphical user interface (GUI) element that shows a plurality of diagrammatical representations of the plurality of terminals in positions corresponding to the respective positions of the plurality of terminals on the electrical safety analyzer and that distinguishes diagrammatical representations of the one or more terminals from diagrammatical representations of remaining terminals of the plurality of terminals.

4. The electrical safety analyzer as claimed in claim 2, wherein the controller is configured to provide the multimodal guidance by:
causing remaining light indicators of the plurality of light indicators to refrain from illuminating.

5. The electrical safety analyzer as claimed in claim 2, wherein the controller configured to:
cause the one or more light indicators positioned in association with the one or more terminals to illuminate by emitting light having a color;
cause the display to display a spatial visualization interface with a positional information graphical user interface (GUI) element that shows a plurality of diagrammatical representations of the plurality of terminals in positions corresponding to the respective positions of the plurality of terminals on the electrical safety analyzer and that distinguishes diagrammatical representations of the one or more terminals from diagrammatical representations of remaining terminals of the plurality of terminals, wherein:
the positional information GUI element distinguishes the diagrammatical representations of the one or more terminals from the diagrammatical representations of the remaining terminals by:
associating the diagrammatical representations of the one or more terminals with the color of the light emitted by the one or more light indicators; and
associating the diagrammatical representations of the remaining terminals with a different color.

6. The electrical safety analyzer as claimed in claim 5, wherein associating the diagrammatical representations of the one or more terminals with the color of the light emitted by the one or more light indicators includes: displaying the diagrammatical representations in the color, surrounding the diagrammatical representations by the color or positioning the diagrammatical representations adjacent to the color.

7. The electrical safety analyzer as claimed in claim 1, comprising:
a plurality of relays corresponding to the plurality of terminals, respectively, and operable to operate in an open state or a closed state,
wherein the controller is configured to, during a time when the controller provides the multimodal guidance to couple the one or more terminals to the one or more applied parts:
operate relays corresponding to the one or more terminals in the closed state; and
operate remaining relays of the plurality of relays corresponding to remaining terminals of the plurality of terminals to operate in the open state to isolate the remaining terminals.

8. The electrical safety analyzer as claimed in claim 1, wherein the controller is configured to:
continuously provide the multimodal guidance until the one or more terminals are coupled to the one or more applied parts.

9. The electrical safety analyzer as claimed in claim 1, wherein:
the controller is configured to receive a user configuration that indicates a number of the one or more applied parts, and
the controller associates the one or more applied parts with a color that is different from colors of remaining applied parts.

10. The electrical safety analyzer as claimed in claim 1, wherein the controller is configured to:
determine that an applied part of the one or more applied parts is erroneously connected; and
in response to determining that the applied part is erroneously connected, cause an alert to be output to a user and refrain from performing the test on the one or more applied parts.

11. The electrical safety analyzer as claimed in claim 1, wherein the controller is configured to:
sequentially perform a plurality of tests of a multi-part test, the plurality of tests including the test as a first test and including a second test.

12. The electrical safety analyzer as claimed in claim 11, wherein the controller is configured to:
identify one or more second terminals applicable to the second test of the multi-part test; and
after providing the multimodal guidance for the first test of the multi-part test, provide multimodal guidance to couple the one or more second terminals of the plurality of terminals to one or more second applied parts.

13. A method, comprising:
identifying, for a test performed on a device under test, one or more terminals of a plurality of terminals on an electrical safety analyzer; and
providing multi-modality guidance to couple the one or more terminals to one or more applied parts of the device under test.

14. The method as claimed in claim 13, wherein providing the multi-modality guidance includes:
causing one or more light indicators positioned in association with the one or more terminals to illuminate.

15. The method as claimed in claim 13, wherein providing the multi-modality guidance includes:
causing a display to display a spatial visualization interface with a positional information graphical user interface (GUI) element that shows a plurality of diagrammatical representations of the plurality of terminals in positions corresponding to respective positions of the plurality of terminals on the electrical safety analyzer and that distinguishes diagrammatical representations of the one or more terminals from diagrammatical representations of remaining terminals of the plurality of terminals.

16. The method as claimed in claim 14, wherein providing multi-modality guidance includes:
causing remaining light indicators of a plurality of light indicators to refrain from illuminating.

17. An electrical safety analyzer, comprising:
a controller; and
memory having stored thereon executable instructions that, when executed by the controller, cause the controller to:
identify, for a test performed on a device under test, one or more terminals of a plurality of terminals on the electrical safety analyzer; and
provide multi-modality guidance to couple the one or more terminals to one or more applied parts of the device under test.

18. The electrical safety analyzer as claimed in claim 17, wherein providing the multi-modality guidance includes:
causing one or more light indicators positioned in association with the one or more terminals to illuminate.

19. The electrical safety analyzer as claimed in claim 17, wherein providing the multi-modality guidance includes:
causing a display to display a spatial visualization interface with a positional information graphical user interface (GUI) element that shows a plurality of diagrammatical representations of the plurality of terminals in positions corresponding to respective positions of the plurality of terminals on the electrical safety analyzer and that distinguishes diagrammatical representations of the one or more terminals from diagrammatical representations of remaining terminals of the plurality of terminals.

20. The electrical safety analyzer as claimed in claim 18, wherein providing the multi-modality guidance includes:
causing remaining light indicators of a plurality of light indicators to refrain from illuminating.
